(19) United States
(12) Patent Application Publication
(10) Pub. No.: US 2019/0157356 A1
(43) Pub. Date: May 23, 2019

(54) OLED DISPLAY DEVICE, CONTROL METHOD AND MANUFACTURING METHOD THEREOF

(71) Applicant: BOE Technology Group Co., Ltd., Beijing (CN)

(72) Inventors: Changfeng Li, Beijing (CN); Haisheng Wang, Beijing (CN); Yingming Liu, Beijing (CN); Xiaoliang Ding, Beijing (CN); Rui Xu, Beijing (CN); Lijun Zhao, Beijing (CN); Pengpeng Wang, Beijing (CN); Wei Liu, Beijing (CN)

(21) Appl. No.: 16/095,982

(22) PCT Filed: Mar. 14, 2018
(86) PCT No.: PCT/CN2018/078971

§ 371 Date: Oct. 24, 2018

(30) Foreign Application Priority Data
May 3, 2017 (CN) 201710305792.7

(51) Int. Cl. H01L 27/32; G06F 3/041; G06F 3/044; H01L 51/52; G09G 3/3225

(52) U.S. Cl. CPC H01L 27/323; G06F 3/0412; G06F 3/0416; G06F 3/044; G09G 2300/0426; G09G 3/3225; G09G 2310/08; G09G 2300/0439; H01L 51/5256

(57) ABSTRACT

An OLED display device, and control method and manufacturing method thereof are provided, in the field of display technology. The OLED display device includes: a base substrate (01), wherein a plurality of OLEDs (02) arranged in an array are disposed on the base substrate (01), an area of the base substrate (01) where the OLEDs (02) are not disposed is provided with touch electrodes (03), the touch electrodes (03) are connected to a touch integrated circuit IC (1) in the OLED display device, and the touch electrodes (03) and the OLEDs (02) are located on the same surface of the base substrate (01), thereby solving the problem that the entire OLED display device is too thick and reducing the thickness of the entire OLED display device, which can be applied in the OLED display device.

This is a 371 of PCT Patent Application Serial No. PCT/CN2018/078971 filed Mar. 14, 2018, which application claims priority to Chinese Patent Application No. 201710305792.7, filed on May 3, 2017 and titled “OLED DISPLAY DEVICE AND CONTROL METHOD THEREOF”, the disclosure of which are incorporated herein by reference in its entirety.

### TECHNICAL FIELD

The present disclosure relates to an OLED display device, and control method and manufacturing method thereof.

### BACKGROUND

With the development of the display technology, the organic light-emitting diode (OLED) display device with a touch function has been widely used. Exemplarily, the OLED display device with the touch function may comprise an OLED display substrate, a cover plate, and a touch panel that are superposed.

In the related art, the touch panel comprises a base substrate and a touch electrode disposed on the base substrate. The touch electrode is connected to a touch integrated circuit (IC). During the implementation of the touch function of the OLED display panel, an AC signal is applied to the touch electrode through the touch IC, and a capacitance formed by the touch electrode and the ground is obtained. Therefore, a touched position on the OLED display panel is further determined, and the OLED display panel is controlled to display a corresponding image according to the touched position on the OLED display panel.

In the OLED display device having the touch function, the OLED display device further comprises the touch panel. Therefore, the entire OLED display device is relatively thick.

### SUMMARY

There is provided in the present disclosure an OLED display device, and control method and manufacturing method thereof.

In a first aspect, there is provided an organic light-emitting diode (OLED) display device, comprising:

a base substrate, wherein a plurality of OLEDs arranged in an array are disposed on the base substrate, an area of the base substrate where the OLEDs are not disposed is provided with a touch electrode, the touch electrode is connected to a touch integrated circuit (IC) in the OLED display device, and the touch electrode and the OLEDs are located on the same surface of the base substrate.

Optionally, the base substrate comprises n touch areas, n being an integer greater than or equal to 2, and

each of the touch areas of the base substrate is provided therein with a plurality of OLEDs, and touch electrodes located at gaps of adjacent OLEDs.

Optionally, the base substrate comprises: a display area and a non-display area, and the display area comprises the n touch areas; and the non-display area of the base substrate is provided therein with n connecting wires in one to one correspondence with the n touch areas, one end of each of the n connecting wires is connected to the touch IC, and the other end of each of the connecting wires is connected to the touch electrodes provided in the corresponding touch area.

Optionally, four OLEDs arranged in an array are disposed within each of the touch areas, the four OLEDs comprise two rows of OLEDs and two columns of OLEDs, and the touch electrodes are in a cross shape.

Optionally, the touch electrode is a self-capacitance touch electrode.

Optionally, the base substrate provided with the OLEDs is provided with a thin film encapsulation layer;

the base substrate provided with the thin film encapsulation layer is provided with the touch electrodes; and

the base substrate provided with the touch electrodes is provided with an insulating layer.

Optionally, the thin film encapsulation layer comprises a first silicon nitride layer, a silicon carbonitride layer and a second silicon nitride layer which are sequentially superposed in a direction away from the base substrate, and the insulating layer is made of silicon nitride.

Optionally, the material of the touch electrodes is the same as the material of the connecting wires.

Optionally, the insulating layer covers the touch electrodes and the connecting wires.

Optionally, the display device further comprises: a cover plate, and the OLEDs are disposed between the base substrate and the cover plate.

In a second aspect, there is provided a control method of an OLED display device, configured to control the OLED display device according to the first aspect, and comprising:

during a touch period of the OLED display device, inputting, by a touch integrated circuit (IC), a touch alternating current (AC) signal to each of the touch electrodes in the OLED display device, and collecting a capacitance formed by each of the touch electrodes and the ground; and

determining, by the touch IC, whether each of the touch electrodes is touched according to the collected capacitance.

Optionally, each OLED in the OLED display device is connected to a display control circuit, and the method further comprises:

during the touch period, inputting, by the display control circuit, a display AC signal synchronized with the touch AC signal to a cathode of each OLED; and

during a display period of the OLED display device, inputting, by the display control circuit, a display direct current (DC) signal to the cathode of each OLED.

Optionally, an amplitude of the touch AC signal is equal to an amplitude of the display AC signal.

Optionally, the display control circuit comprises a gate electrode driving circuit and a display IC, the display control circuit has at least one signal terminal, each of the OLEDs is connected to the at least one signal terminal of the display control circuit via a pixel circuit,

during the touch period, the signal on each signal terminal is an AC signal; and

during the display period, the signal on each signal terminal is a DC signal.

Optionally, the at least one signal terminal comprises a power source signal terminal, and the method further comprises:

during the touch period, controlling, by the display control circuit, a circuit between an anode of each OLED and the power source signal terminal to be in an off state; and

during a light-emitting stage in the display period, controlling, by the display control circuit, the circuit between the anode of each OLED and the power source signal terminal to be in an on state.

Optionally, the pixel circuit comprises eight transistors and a capacitor, the at least one signal terminal comprises: a reset terminal, a reference electrode terminal, a gate line terminal, a power source signal terminal, a data signal terminal, a control signal terminal, a reference signal input terminal and a cathode terminal, and the method further comprises:

during the touch period, controlling, by the display control circuit, the transistors having gate electrodes connected to the control signal terminal in the eight transistors to be in an off state; and

during the light-emitting stage in the display period, controlling, by the display control circuit, the transistors having the gate electrodes connected to the control signal terminal in the eight transistors to be in an on state.

Optionally, the eight transistors are all N-type transistors; or the eight transistors are all P-type transistors.

In a third aspect, there is provided a manufacturing method of an OLED display device, comprising:

providing a base substrate;

forming a plurality of OLEDs arranged in an array on the base substrate; and

forming a touch electrode on the base substrate, wherein the touch electrode is disposed in an area of the base substrate where the OLEDs are not disposed, the touch electrode is connected to a touch IC in the OLED display device, and the touch electrode and the OLEDs are located on the same surface of the base substrate.

Optionally, after forming a plurality OLEDs arranged in an array on the base substrate, the method further comprises: forming a thin film encapsulation layer on the base substrate;

forming a touch electrode on the base substrate comprises: forming the touch electrode on the base substrate provided with the thin film encapsulation layer; and

after forming the touch electrode on the base substrate, the method further comprises: forming an insulating layer on the base substrate provided with the touch electrode.

Optionally, the base substrate comprises: a display area and a non-display area, and the display area comprises n touch areas; the method further comprises:

forming n connecting wires in one to one correspondence with the n touch areas in the non-display area of the base substrate, wherein one end of each of the n connecting wires is connected to the touch IC, and the other end of each of the connecting wires is connected to the touch electrodes disposed in the corresponding touch area.

### BRIEF DESCRIPTION OF THE DRAWINGS

FIG. 1 is a schematic diagram of a partial structure of an OLED display device according to an embodiment of the present disclosure;

FIG. 2 is a schematic diagram of a partial structure of another OLED display device according to an embodiment of the present disclosure;

FIG. 3 is a schematic diagram of a partial structure of yet another OLED display device according to an embodiment of the present disclosure;

FIG. 4 is a schematic diagram of a structure of an OLED display device according to an embodiment of the present disclosure;

FIG. 5 is a flowchart of a control method of an OLED display device according to an embodiment of the present disclosure;

FIG. 6 is a flowchart of a control method of another OLED display device according to an embodiment of the present disclosure;

FIG. 7 is a schematic diagram of a signal according to an embodiment of the present disclosure;

FIG. 8 is a schematic diagram of a structure of a pixel circuit according to an embodiment of the present disclosure;

FIG. 9 is a schematic diagram of a structure of a gate signal output module according to an embodiment of the present disclosure;

FIG. 10 is an oscillogram of a signal on a signal terminal related to a gate signal output module according to an embodiment of the present disclosure;

FIG. 11 is a schematic diagram of a structure of a control signal output module according to an embodiment of the present disclosure;

FIG. 12 is an oscillogram of a signal on a signal terminal related to a control signal output module according to an embodiment of the present disclosure;

FIG. 13 is a flowchart of a manufacturing method of an OLED display device according to an embodiment of the present disclosure;

FIG. 14 is a flowchart of another manufacturing method of an OLED display device according to an embodiment of the present disclosure;

FIG. 15 is a schematic diagram of a partial structure of the OLED display device shown in FIG. 4 according to an embodiment of the present disclosure;

FIG. 16 is a schematic diagram of another partial structure of the OLED display device shown in FIG. 4 according to an embodiment of the present disclosure;

FIG. 17 is a schematic diagram of yet another partial structure of the OLED display device shown in FIG. 4 according to an embodiment of the present disclosure; and

FIG. 18 is a schematic diagram of still yet another partial structure of the OLED display device shown in FIG. 4 according to an embodiment of the present disclosure.

### DETAILED DESCRIPTION

In order to make the principle and advantages of the present disclosure clearer, the embodiments of the present disclosure will be further described in detail below with reference to the accompanying drawings.

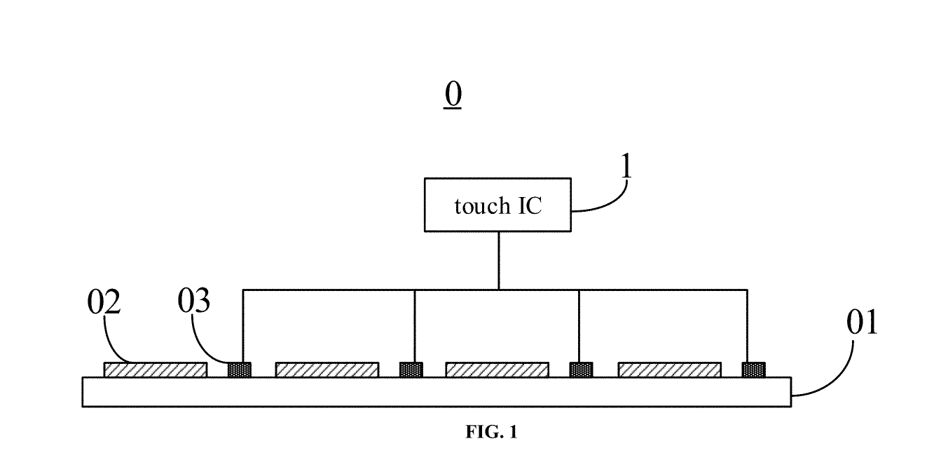

FIG. 1 is a schematic diagram of a partial structure of an OLED display device according to an embodiment of the present disclosure, and FIG. 1 illustrates a schematic diagram of a cross-section of the OLED display device. As shown in FIG. 1, the OLED display device 0 may comprise a base substrate 01.

A plurality of OLEDs 02 arranged in an array are disposed on the base substrate 01. The area of the base substrate 01 where the OLEDs 02 are not disposed is provided with a touch electrode 03. The touch electrode 03 is connected to a touch IC 1 in the OLED display device.

It should be noted that the OLED and the touch electrode in the embodiments of the present disclosure may be located on the same surface of the base substrate. For example, the plurality of OLEDs arranged in an array are disposed on a target surface of the base substrate, and the area on the target surface where the OLEDs are not disposed is provided with the touch electrode.

In summary, in the OLED display device provided in the embodiments of the present disclosure, the position on the base substrate where the OLEDs are not disposed is provided with the touch electrode, and the touch electrode is connected to the touch IC. Therefore, the touch function can be realized directly via the touch IC and the touch electrode on the base substrate without superposing a touch panel on an OLED display panel, thereby reducing the number of the base substrates in the entire OLED display device and reducing the thickness of the entire OLED display device.

In addition, since the thickness of the entire OLED display device is reduced, the manufacturing cost of the OLED display device is also reduced correspondingly.

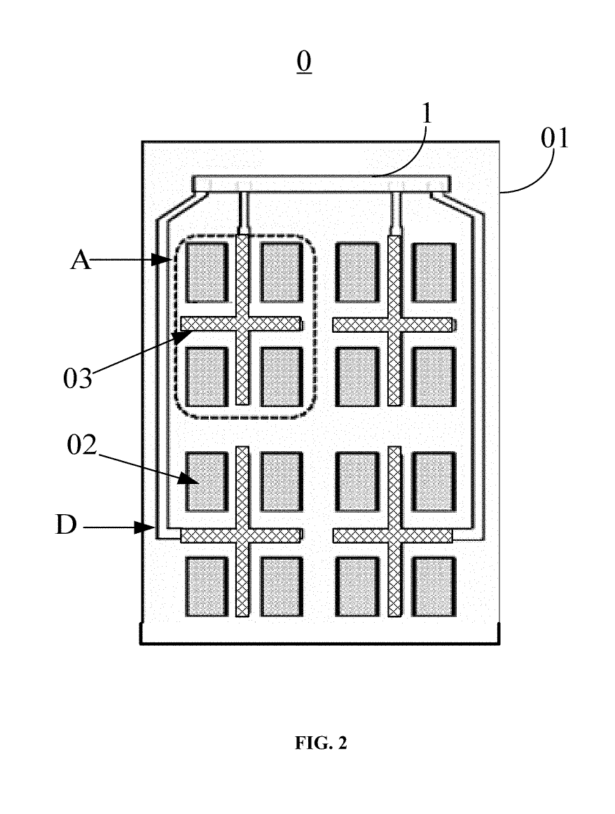

FIG. 2 is a schematic diagram of a partial structure of another OLED display device according to an embodiment of the present disclosure, and FIG. 2 shows a top diagram of the OLED display device. As shown in FIG. 2, the base substrate 01 may comprise n touch areas A, and n is an integer greater than or equal to 2. It should be noted that in FIG. 2, as an example, n is equal to 4. In practical application, n may also be other integers greater than or equal to 2, for example, n may be equal to 100.

Each touch area A of the base substrate 01 is provided therein with a plurality of OLEDs 02 and touch electrodes 03 located at the gaps of the adjacent OLEDs 02. In FIG. 2, as an example, four OLEDs 02 comprising two rows of OLEDs and two columns of OLEDs are disposed in each touch area A, and the touch electrodes 03 are in a cross shape. In practical application, the number of the OLEDs provided in the touch area A may not be four, and the number of the OLEDs in any two touch areas A may not be equal, which is not limited in the embodiments of the present disclosure.

Further, the base substrate 01 may comprise: a display area and a non-display area. The display area may comprise the n touch areas A, that is, the plurality of touch areas A are located in the display area of the base substrate 01. The non-display area of the base substrate 01 may be provided therein with n connecting wires D in one-to-one corresponding to the n touch areas. One end of each of the n connecting wires B is connected to the touch IC 1. The other end of each connecting wire B is connected to the touch electrodes 03 disposed in the corresponding touch area A.

That is, touch electrodes 03 are disposed in each touch area A, and the shape of the touch electrode 03 is not limited in the embodiments of the present disclosure. However, it needs to be ensured that the touch electrodes 03 are disposed at the gaps between adjacent OLEDs in the touch area. The touch electrodes 03 in each touch area A may be connected to the touch IC 1 via the connecting wire B corresponding to the touch area A, so that each of the touch electrodes 03 disposed on the base substrate 01 is connected to the touch IC.

Exemplarily, the touch electrode 03 in the embodiment of the present disclosure may be a single-layer electrode, a plurality of single-layer electrodes (i.e., a plurality of touch electrodes) are all connected to the touch IC, and the plurality of single-layer electrodes are self-capacitance touch electrodes. Moreover, since the electrode material required for the self-capacitance touch electrodes is less, the cost of manufacturing the OLED display device is further reduced.

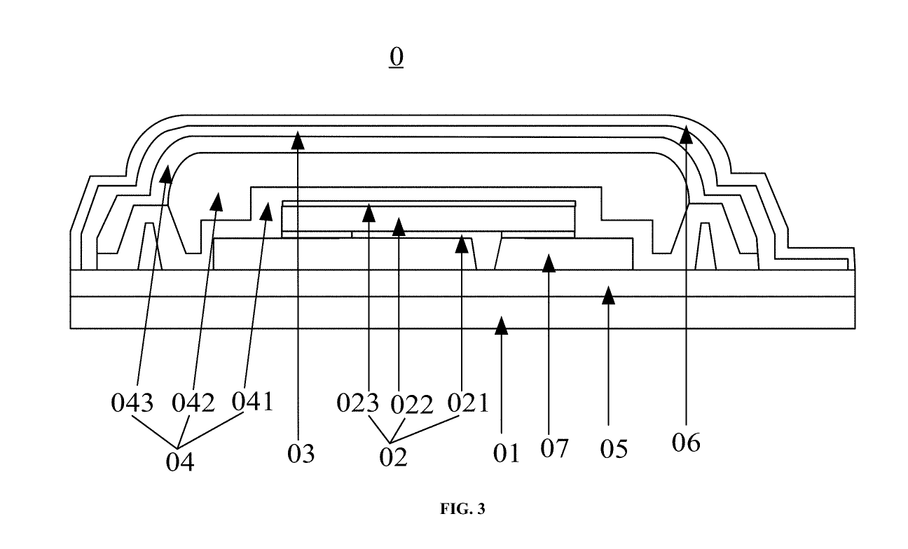

Further, in order to prevent mutual interference between the touch electrodes and the OLEDs on the base substrate, it is necessary to provide a film layer having an insulating function between the OLEDs and the touch electrodes. FIG. 3 is a schematic diagram of a partial structure of still another OLED display device according to an embodiment of the present disclosure, and FIG. 3 shows a schematic diagram of a cross-section of the OLED display device. As shown in FIG. 3, a thin film encapsulation layer 04 is disposed on the base substrate 01 provided with the OLEDs 02, and a touch electrode 03 is disposed on the base substrate 01 provided with the thin film encapsulation layer 04.

In addition, in order to prevent the touch electrode from being in direct contact with the air, which causes the touch electrode to be oxidized and to lose the original characteristics thereof, the insulating layer 06 needs to cover the touch electrode 03. Still referring to FIG. 3, the base substrate 01 provided with the touch electrodes 03 may be provided the insulating layer 06.

When the OLED display device is manufactured, the plurality of OLEDs arranged in an array may be firstly formed on the base substrate, and then the thin film encapsulation layer is formed on the base substrate provided with the OLEDs. Exemplarily, the material of the touch electrodes and the material of the connecting wires may be the same conductive material. After the thin film encapsulation layer is formed, a conductive material layer may be firstly formed on the thin film encapsulation layer, and then the conductive material layer is processed by using a one-time patterning process to obtain the touch electrodes and connecting wires. Finally, the insulating layer may be formed on the touch electrodes. Optionally, the insulating layer may only cover the touch electrodes, without the connecting wires. The insulating layer may also cover the touch electrodes and the connecting wires at the same time, which is not limited in the embodiments of the present disclosure.

Exemplarily, continuing to refer to FIG. 3, the thin film encapsulation (TFE) layer may comprise a first silicon nitride layer 041, a silicon carbonitride layer 042, and a second silicon nitride layer 043 that are superposed together. The insulating layer 06 may also be a silicon nitride layer, which is not limited by the embodiments of the present disclosure. Further, a plurality of pixel circuits 05 may also be formed on the base substrate 01, the base substrate 01 provided with the pixel circuits 05 may be provided with a passivation layer 07, and the base substrate provided with the passivation layer 07 may be provided with the OLEDs 02 arranged in an array. Each OLED may comprise an anode 021, a light-emitting layer 022, and a cathode 023 that are superposed. The anode 021 is connected to the pixel circuit through a via hole on the passivation layer 07, and each pixel circuit is connected to one OLED.

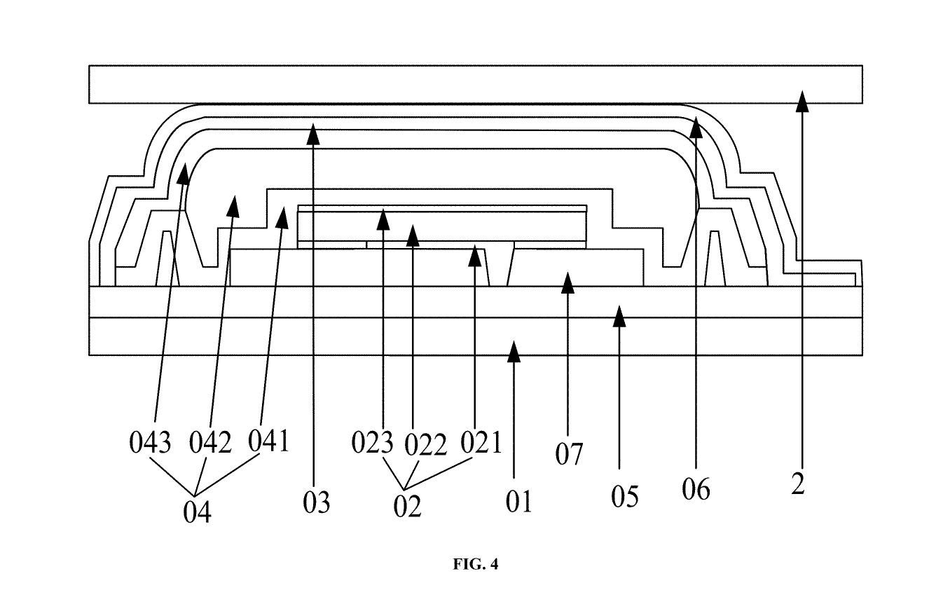

FIG. 4 is a schematic diagram of a structure of an OLED display device according to an embodiment of the present disclosure. As shown in FIG. 4, the OLED display device 0 may further comprise a cover plate 2, such that the OLED is disposed between the base substrate and the cover plate 2. It should be noted that the OLED display device comprising the cover plate is taken as an example in the embodiments of the present disclosure. In practical application, the OLED display device may not comprise the cover plate, which is not limited in the embodiments of the present disclosure.

Exemplarily, the OLED display device may be any product or part having a display function, such as an electronic paper, a mobile phone, a tablet, a TV, a display, a laptop computer, a digital phone frame, a navigator, and the like.

In summary, in the OLED display device provided in the embodiments of the present disclosure, the position on the base substrate where the OLEDs are not disposed is provided with the touch electrodes, and the touch electrodes are connected to the touch IC. Therefore, the touch function can be realized directly through the touch IC and the touch electrode on the base substrate without superposing a touch panel on an OLED display panel, thereby reducing the number of the base substrates in the entire OLED display device and reducing the thickness of the entire OLED display device.

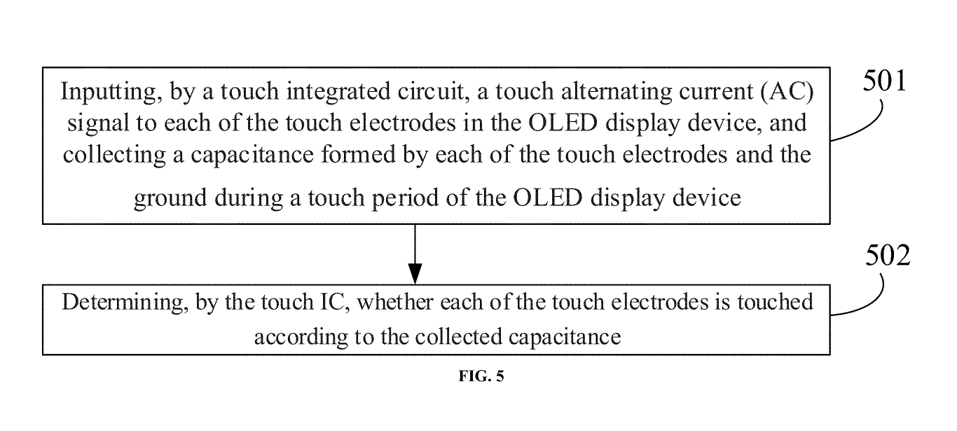

FIG. 5 is a flowchart of a control method of an OLED display device according to an embodiment of the present disclosure. The control method can be applied to any one of the OLED display device shown in FIG. 1 to FIG. 4. As shown in FIG. 5, the control method of an OLED display device may include the following steps.

In step 501, during a touch period of the OLED display device, a touch IC inputs a touch alternative current (AC) signal to each of the touch electrodes in the OLED display device, and collects a capacitance formed by each of the touch electrodes and the ground.

In step 502, the touch IC determines whether each of the touch electrodes is touched according to the collected capacitance.

In summary, in the control method of an OLED display device provided in the embodiments of the present disclosure, the touch AC signal is input to each of the touch electrodes in the OLED display device, and the capacitance formed by each touch electrode and the ground is collected. Then, according to the capacitance formed by each touch electrode and the ground, whether each of the touch electrodes is touched can be determined, thereby realizing the touch function of the OLED display device.

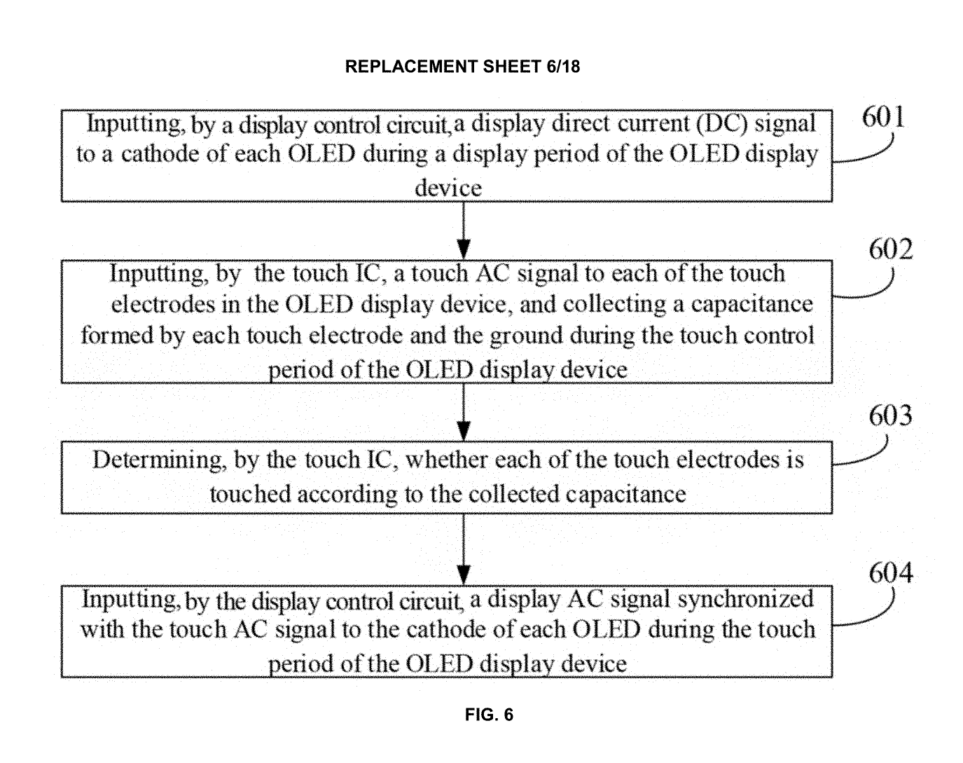

FIG. 6 is a flowchart of another control method of an OLED display device according to an embodiment of the present disclosure. The method is configured to control the OLED display device shown in any one of FIG. 1 to FIG. 4. As shown in FIG. 6, the control method of an OLED display device may comprise the following steps.

In step 601, during a display period of the OLED display device, a display control circuit inputs a display direct current (DC) signal to a cathode of each OLED.

It should be noted that each OLED in the OLED display device is connected to the display control circuit (the display control circuit is not shown in the drawing of the specification). The display control circuit and a touch IC can be integrated in the same IC module, or the display control circuit and the touch IC can be independently disposed from each other.

Exemplarily, the working period of the OLED display device may be divided into multiple display periods and multiple touch periods, and the number of the display periods and the number of the touch periods may be different or the same. During the display period of the OLED display device, a first display DC signal may be input to the cathode of each OLED by the display control circuit, and meanwhile, a second display DC signal may also be input to an anode of each OLED by the display control circuit, thereby controlling the OLED display device to display an image. Optionally, during the display period of the OLED display device, the touch IC does not need to input any electrical signal to the touch electrode.

In step 602, during the touch period of the OLED display device, the touch IC inputs a touch AC signal to each of the touch electrodes in the OLED display device, and collects a capacitance formed by each touch electrode and the ground.

In step 603, the touch IC determines whether each of the touch electrodes is touched according to the collected capacitance.

It should be noted that when the touch electrode is not touched, the capacitance formed by the touch electrode and the ground is a preset capacitance value. When the capacitance value formed by certain touch electrode and the ground, and collected by the touch control IC is not the preset capacitance value, it can be determined that the certain touch electrode has been touched. When the capacitance value formed by the touch electrode and the ground, and collected by the touch IC is the preset capacitance value, it can be determined that the certain touch electrode is not touched at the moment.

In step 604, during the touch period of the OLED display device, the display control circuit inputs a display AC signal synchronized with the touch AC signal to the cathode of each OLED.

During the touch period of the OLED display device, the display control circuit may input the display AC signal synchronized with the touch AC signal to the cathode of each OLED. Optionally, the value of amplitude of the touch AC signal may be equal to the value of amplitude of the display AC signal. That is, when the touch IC inputs the touch AC signal to the touch electrode, the display control circuit can input the display AC signal that is synchronized and has equal value of amplitude to the cathode of each display OLED (that is, the display AC signal and the touch AC signal are the same).

It should be noted that in the OLED display device, each OLED has the anode and the cathode, the anode is disposed close to the base substrate and away from the touch electrode, and the cathode is disposed away from the base substrate and close to the touch electrode. During the display period of the OLED display device, the DC signal is input to the cathode of each OLED. However, during the touch period of the OLED display device, the AC signal is input to the touch electrode. At this point, if the DC signal is still input to the cathode of the OLED, the cathode has a larger influence on the capacitance collected by the touch IC from the touch electrode. During different time periods, the influences of the cathode on the signal collected by the touch IC are different, which affects the touch accuracy.

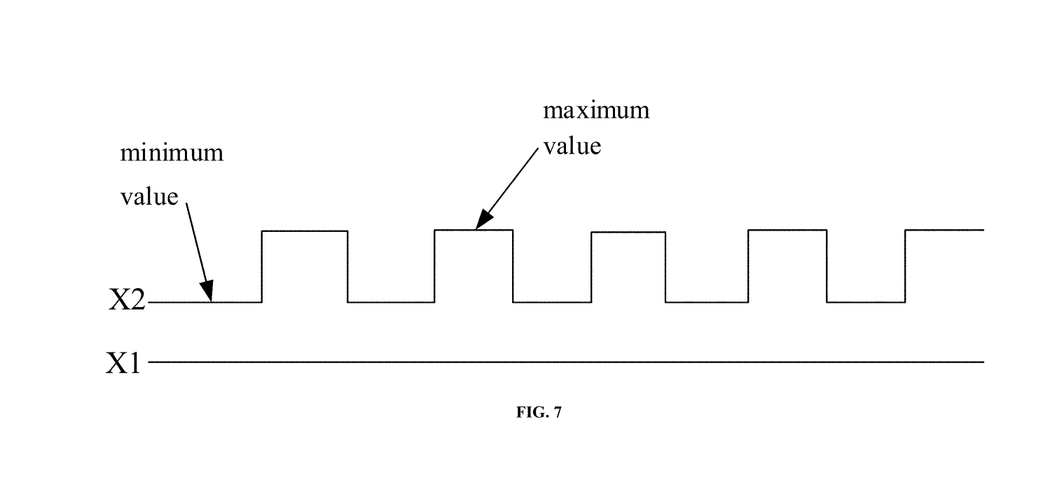

Exemplarily, FIG. 7 is a schematic diagram of a signal according to an embodiment of the present disclosure. As shown in FIG. 7, during the touch period of the OLED display device, if the DC signal X1 is input to the cathode of an OLED, and the AC signal X2 is input to the touch electrode adjacent to the OLED, then when the value of the AC signal X2 is the maximum value, the difference value between the AC signal X2 and the DC signal X1 is larger, and the DC signal X1 has a greater influence on the capacitance collected by the touch IC from the touch electrode. When the value of the AC signal X2 is the minimum value, the difference value between the AC signal X2 and the DC signal X1 is smaller, and the DC signal X1 has less influence on the capacitance collected by the touch IC from the touch electrode. That is, during the entire touch period of the OLED display device, the influence of the DC signal X1 on the capacitance collected by the touch IC from the touch electrode continuously changes. Therefore, it is relatively difficult to determine whether the touch electrode is touched according to the collected capacitance.

In the embodiments of the present disclosure, when the touch IC inputs the touch AC signal to the touch electrode during the touch period of the OLED display device, the display control circuit can input the display AC signal same as the touch AC signal to the cathode of the OLED. Therefore, the influence of the cathode on the signal collected by the touch IC is always consistent during the touch period. Each time the touch electrode is determined to be touched, the collected capacitor value can be subjected to the same processing. Whether the touch electrode is touched can be accurately determined according to the processed capacitance value, thereby improving the touch accuracy.

Further, each OLED is connected to the display control circuit by a pixel circuit. Exemplarily, the display control circuit may comprise a gate electrode driving circuit and a display IC that are connected. The gate electrode driving circuit has a reset terminal Reset, a gate line terminal Gate, and a control signal terminal EM. The display IC has a reference electrode terminal Vinit, a power source signal terminal VDD, a data signal terminal SD, a reference signal input terminal Vref, and a cathode terminal VSS. That is, the display control circuit may have at least one signal terminal. The at least one signal terminal may comprise the Reset, Vinit, Gate, VDD, SD, EM, Vref, and VSS.

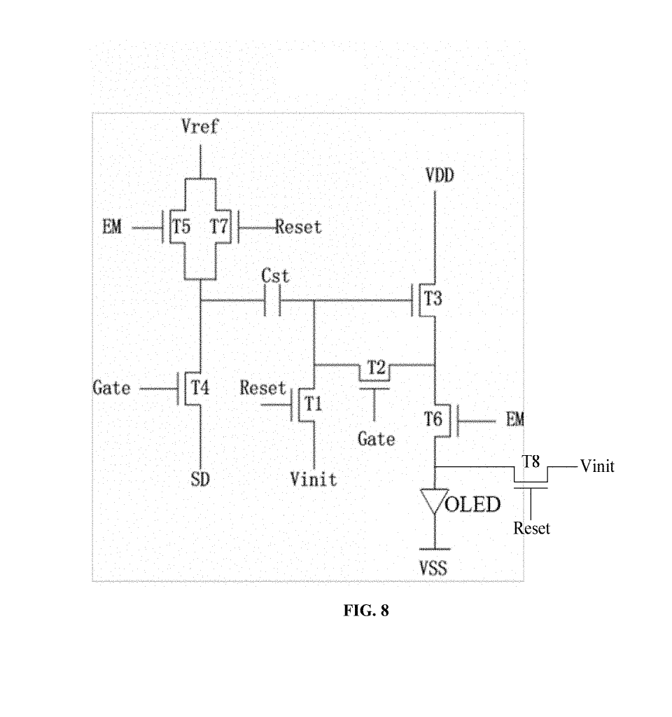

The pixel circuit is connected to the at least one signal terminal. FIG. 8 is a schematic diagram of a structure of the pixel circuit according to an embodiment of the present disclosure. As shown in FIG. 8, the pixel circuit may comprise 8 transistors and a capacitor Cst.

It should be noted that the transistors used in all embodiments of the present disclosure may be thin film transistors or field effect transistors or other devices having the same characteristics. Since the source electrode and drain electrode of the transistor used here are symmetrical, the source electrode and drain electrode are interchangeable. In the embodiments of the present disclosure, in order to distinguish the two electrodes of the transistor except the gate electrode, the two electrodes may comprise a first electrode and a second electrode. For example, the source electrode is the first electrode and the drain electrode is the second electrode, or the drain electrode is the first electrode and the source electrode is the second electrode. According to the form in the drawing, the middle terminal of the transistor is the gate electrode, the signal input terminal is the source electrode, and the signal output terminal is the drain electrode. In addition, the transistor used in the embodiments of the present disclosure may be a P-type transistor or an N-type transistor. The P-type transistor is turned on when the gate electrode is at a low level, and is turned off when the gate electrode is at a high level. The N-type transistor is turned on when the gate electrode is at the high level and is turned off when the gate electrode is at the low level. In the following embodiments, a transistor being a P-type transistor is taken as an example.

The eight transistors in the pixel circuit are a first transistor T1, a second transistor T2, a third transistor T3, a fourth transistor T4, a fifth transistor T5, a sixth transistor T6, a seventh transistor T7, and an eighth transistor T8 respectively. Each transistor has a gate electrode, a first electrode and a second electrode. The second electrode is the drain electrode when the first electrode is the source electrode, and the second electrode is the source electrode when the first electrode is the drain electrode.

The gate electrode of the T1 is connected to the Reset, the first electrode of the T1 is connected to the vinit, and the second electrode of the T1 is connected to one end of the capacitor Cst. The gate electrode of the T2 is connected to the Gate, the first electrode of the T2 is connected to the first electrode of the T6, and the second electrode of the T2 is connected to one end of the Cst. The gate electrode of the T3 is connected to one end of the capacitor Cst, the first electrode of the T3 is connected to the first electrode of the T6, and the second electrode of the T3 is connected to the VDD. The gate electrode of the T4 is connected to the Gate, the first electrode of the T4 is connected to the SD, and the second electrode of the T4 is connected to the other end of the Cst. The gate electrode of the T5 is connected to the EM, the first electrode of the T5 is connected to the other end of the Cst, and the second electrode of the T5 is connected to the Vref. The gate electrode of the T6 is connected to the EM, the second electrode of the T6 is connected to the anode of the OLED, and the first electrode of the T6 is connected to the first electrode of the T2. The gate electrode of the T7 is connected to the Reset, the second electrode of the T7 is connected to the other end of the capacitor Cst, the first electrode of the T7 is connected to the Vref, and the cathode of the OLED is connected to the VSS. The gate electrode of the T8 is connected to the Reset, the first electrode of the T8 is connected to the Vinit, and the second electrode of the T8 is connected to the anode of the OLED.

During the touch period of the OLED display device, the signals on each of the at least one signal terminal are the AC signals. During the display period of the OLED display device, the signals on each signal terminal are the DC signals. That is, in order to ensure that the display control circuit can input the display AC signal to the cathode of the OLED during the touch period, it is necessary to ensure that the signals on each signal terminal of the pixel circuit during the touch period are the AC signals. In order to ensure that during the display period, the display control circuit can input the display DC signal to the cathode input of the OLED, it is necessary to ensure that the signals on each signal terminal of the pixel circuit during the display period are the DC signals.

Optionally, during the touch period of the OLED display device, in order to prevent the influence of the AC signal on the pixel circuit and the display control circuit on light emission of the OLED, the display control circuit needs to control the circuit between the anode of the OLED and the power source signal terminal to be turned off. That is, during the touch period of the OLED display device, the display control circuit can control the circuit between the anode of each OLED and VDD to be in an off state. During a light-emitting stage in the display period, the display control circuit can control the circuit between the anode of each OLED and the VDD to be in an on state. During a reset period and a charging stage in the display period, the display control circuit can control the circuit between the anode of each OLED and the VDD to be in the off state. Exemplarily, during the touch period, the display control circuit may control the sixth transistor (the transistor of which the gate electrode is connected to the control signal terminal) to be in the off state. During the light-emitting stage in the display period, the sixth transistor may be controlled to be in the on state. In addition, since the gate electrode of the fifth transistor is also connected to the control signal terminal, the display control circuit can also control the fifth transistor to be in the off state during the touch period, and during the light-emitting stage in the display period, the display control circuit can also control the fifth transistor to be in the on state.

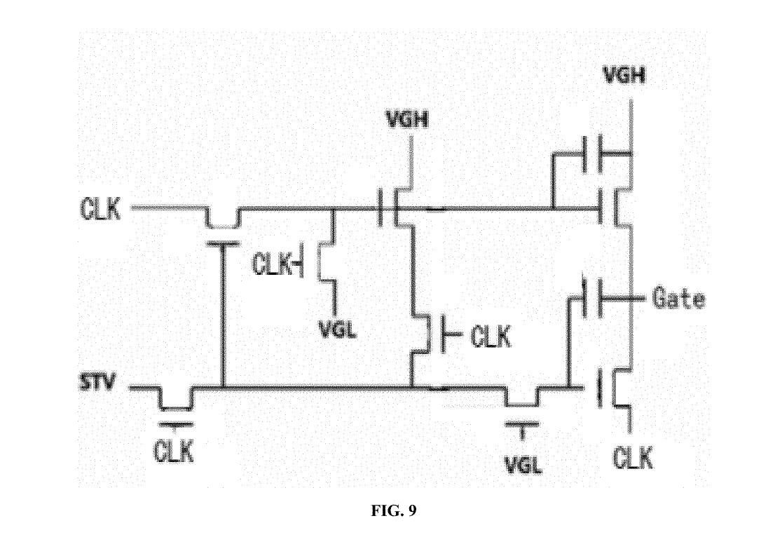

For example, FIG. 9 is a schematic diagram of a structure of a gate signal output module in a gate electrode driving circuit according to an embodiment of the present disclosure. As shown in FIG. 9, the gate signal output module may comprise 8 transistors and 2 capacitors. The gate signal output module is further connected to a high level terminal VGH, a low level terminal VGL, a clock signal terminal CLK and a trigger signal terminal STV, and the output end of the gate signal output module is a gate line terminal connected to the pixel circuit shown in FIG. 8.

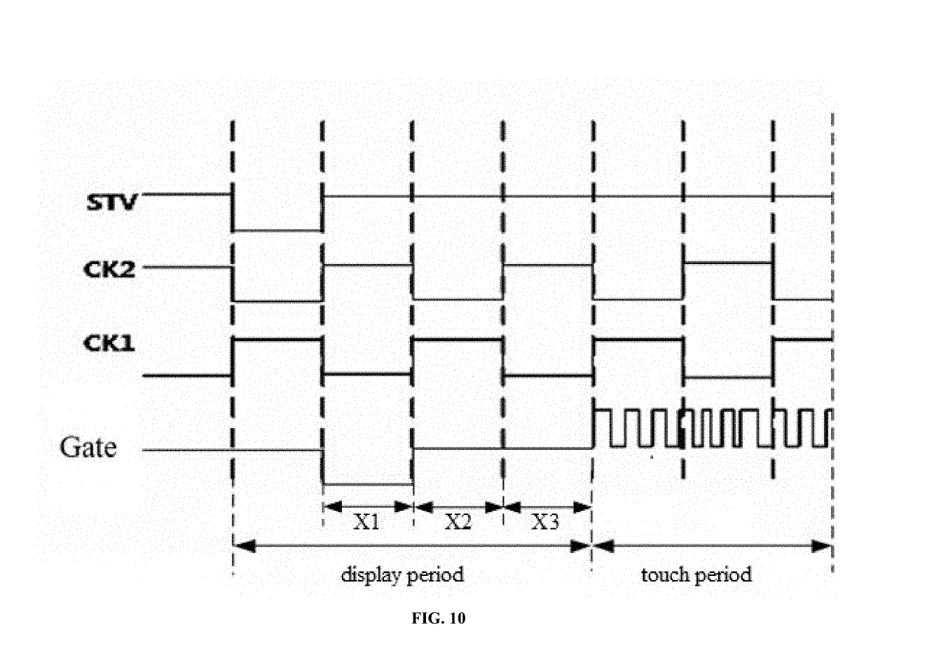

FIG. 10 is an oscillogram of a signal on a signal terminal related to a gate signal output module according to an embodiment of the present disclosure. As shown in FIG. 10, during a pixel circuit charging stage t1 in the display period of the OLED display device, the potential of the signal on the gate line terminal is low. During the light-emitting stages (t2 and t3) in the display period of the OLED display device, the potential of the signal on the gate line terminal is higher, and the signal on the gate line terminal is the DC signal. During the touch period of the OLED display device, the signal on the gate line terminal is the AC signal (that is, the signal output from the VGH is the AC signal). It should be noted that the signal on the clock signal terminal CLK in FIG. 9 may be the first clock signal CK1 or the second clock signal CK2 shown in FIG. 10. The signal on the trigger signal terminal STV in FIG. 9 may be as shown in FIG. 10.

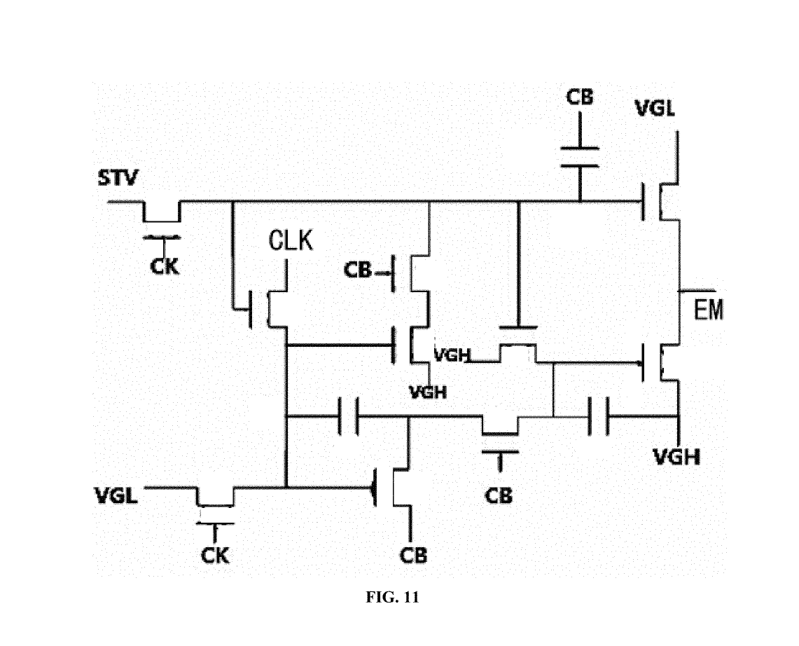

FIG. 11 is a schematic diagram of a structure of a control signal output module in a gate electrode driving circuit according to an embodiment of the present disclosure. As shown in FIG. 11, the control signal output module may comprise 10 transistors and 2 capacitors. The control signal output module is further connected to the high-level terminal VGH, the low-level terminal VGL, the clock signal terminal CK, and a counter-clock signal terminal CB (that is, the signal terminal opposite to the phase of the signal output from the clock signal terminal CK). The output terminal of the control signal output module is the EM to which the pixel circuit shown in FIG. 8 is connected.

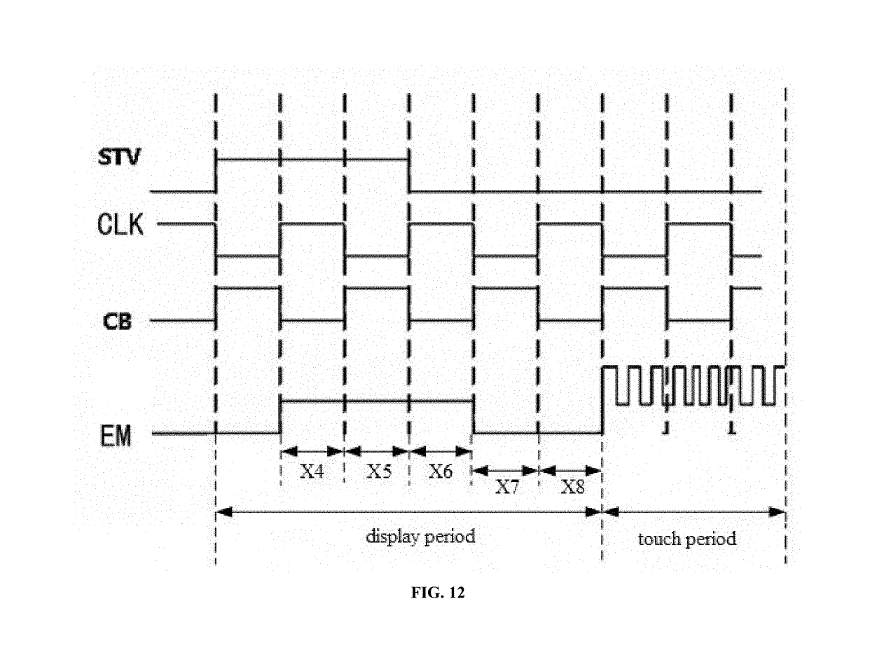

FIG. 12 is an oscillogram of a signal on a signal terminal related to a control signal output module according to an embodiment of the present disclosure. As shown in FIG. 12, during the pixel circuit reset stage and the charging stage (the pixel circuit reset stage and the charging stage are X4, X5, and X6 as shown in FIG. 12) in the display period of the OLED display device, the potential of the signal on the EM is higher; and during the light-emitting stage (X7 and X8) in the display period of the OLED display device, the potential of the signal on the EM is lower, and the signal on the EM is the DC signal. During the touch period of the OLED display device, the potential of the signal on the EM is firstly pulled-up, so that the pulled-up potential is higher than the high potential of the signal on the EM during the reset and charge stages in the display period, and then the AC signal is input into EM through the VGL of only one transistor between it and the EM. Therefore, during the touch period of the OLED display device, by pulling-up the potential on the EM, the transistor T6 connected to the OLED in FIG. 8 is in an off state, thereby causing the circuit between the anode of each OLED and the VDD to be in the off state.

Exemplarily, the duration of the touch period of the OLED display device may be from 1 millisecond to 8 milliseconds. That is, since the duration of the touch period is smaller, the human eyes do not feel that the OLED does not emit light since the T6 in FIG. 8 is turned off during the touch period. Therefore, the display effect of the display device will not be affected if the T6 is turned off during the touch period.

In summary, in the control method of an OLED display device provided in the embodiments of the present disclosure, the touch AC signal is input to each touch electrode in the OLED display device, and the capacitance formed by each touch electrode and the ground is collected. Then, according to the capacitance formed by each touch electrode and the ground, whether each touch electrode is touched can be determined, thereby realizing the touch function of the OLED display device.

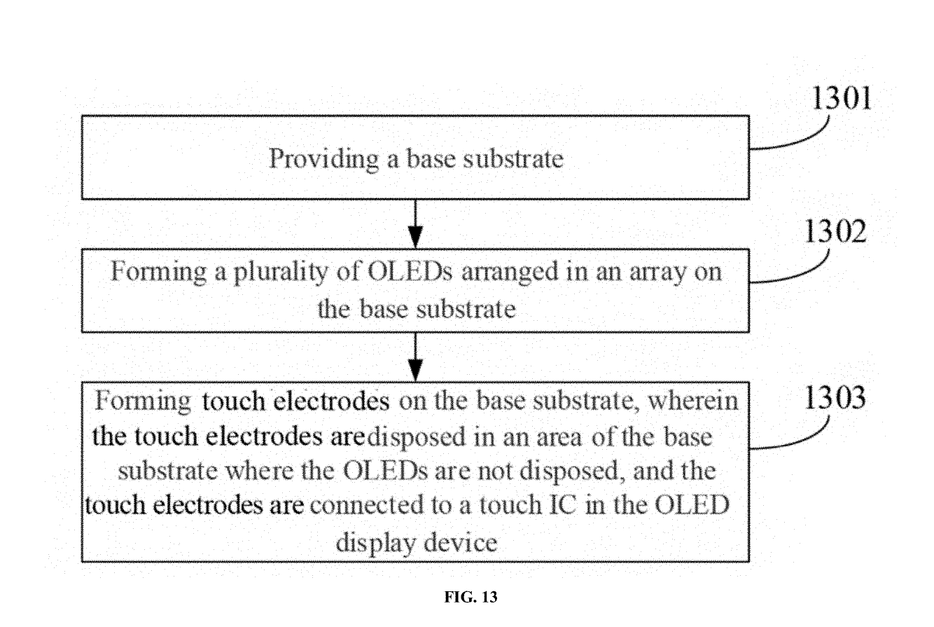

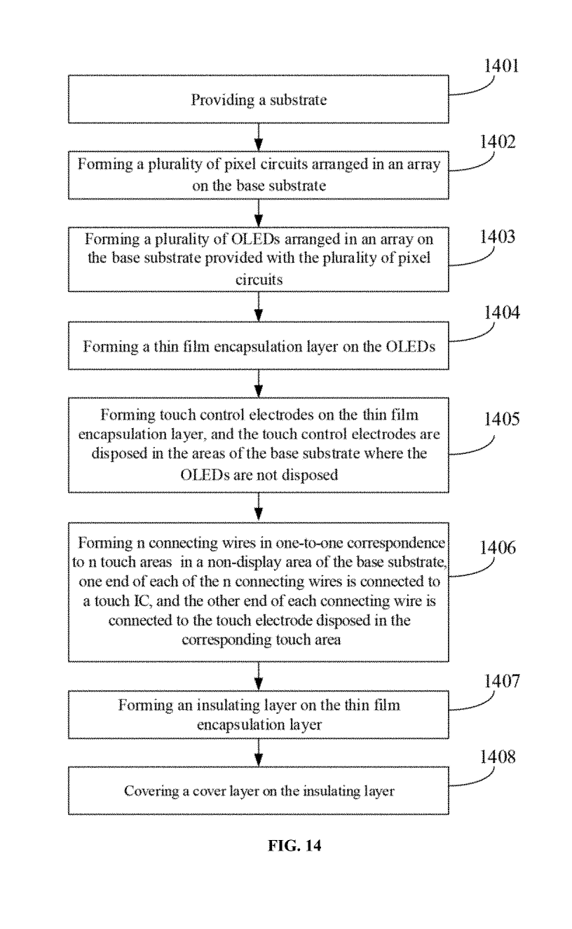

FIG. 14 is a flowchart of a method for manufacturing an OLED display device according to an embodiment of the present disclosure. The OLED display device may be any one of the OLED display devices shown in FIG. 1 to FIG. 4. As shown in FIG. 13, the method for manufacturing an OLED display device may include the following steps.

In step 1301, a base substrate is provided.

In step 1302, a plurality of OLEDs arranged in an array are formed on the base substrate.

In step 1303, a touch electrode is formed on the base substrate, wherein the touch electrode is disposed in an area of the base substrate where the OLEDs are not disposed, the touch electrode is connected to a touch IC in the OLED display device, and the touch electrode and the OLEDs are located on the same surface of the base substrate.

In summary, in the OLED display device manufactured according to the manufacturing method provided by the embodiments of the present disclosure, the position on the base substrate where the OLEDs are not disposed is provided with the touch electrodes, and the touch electrodes are connected to the touch IC. Therefore, the touch function can be realized directly through the touch IC and the touch electrode on the base substrate without superposing a touch panel on an OLED display panel, thereby reducing the number of the base substrates in the entire OLED display device and reducing the thickness of the entire OLED display device.

FIG. 14 is a flowchart of another method for manufacturing an OLED display device according to an embodiment of the present disclosure. The OLED display device may be the OLED display device as shown in FIG. 4. As shown in FIG. 14, the method for manufacturing an OLED display device may comprise the following steps.

In step 1401, a substrate is provided.

Optionally, the base substrate may be a transparent substrate, such as a glass substrate.

In step 1402, a plurality of pixel circuits arranged in an array are formed on the base substrate.

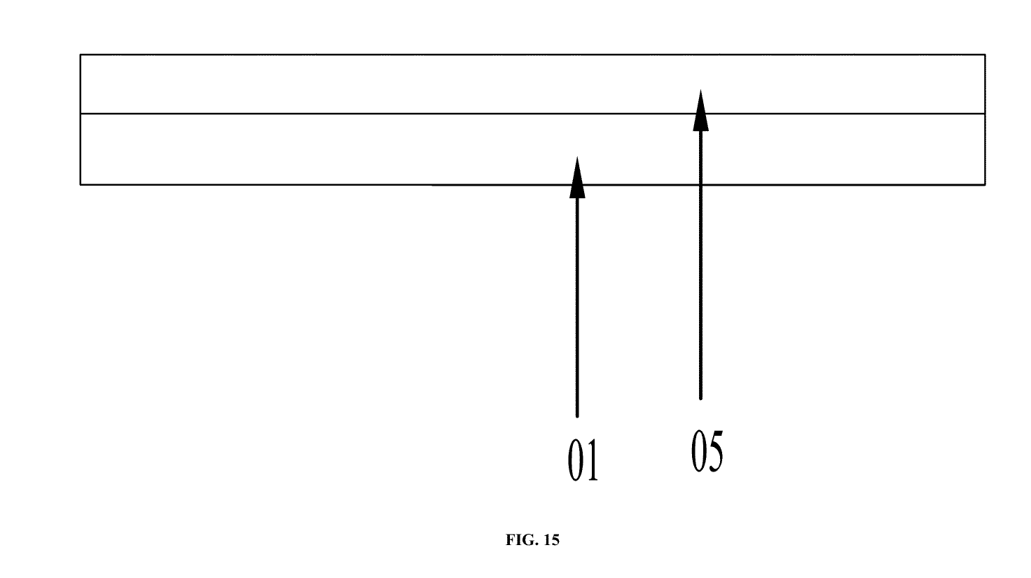

FIG. 15 is a schematic diagram of a partial structure of the OLED display device as shown in FIG. 4 according to an embodiment of the present disclosure. As shown in FIG. 15, a plurality of pixel circuits 05 arranged in an array may be formed on the base substrate 01 in the step 1402. It should be noted that only one pixel circuit 05 is shown in FIG. 15.

In step 1403, a plurality of OLEDs arranged in an array are formed on the base substrate provided with the plurality of pixel circuits.

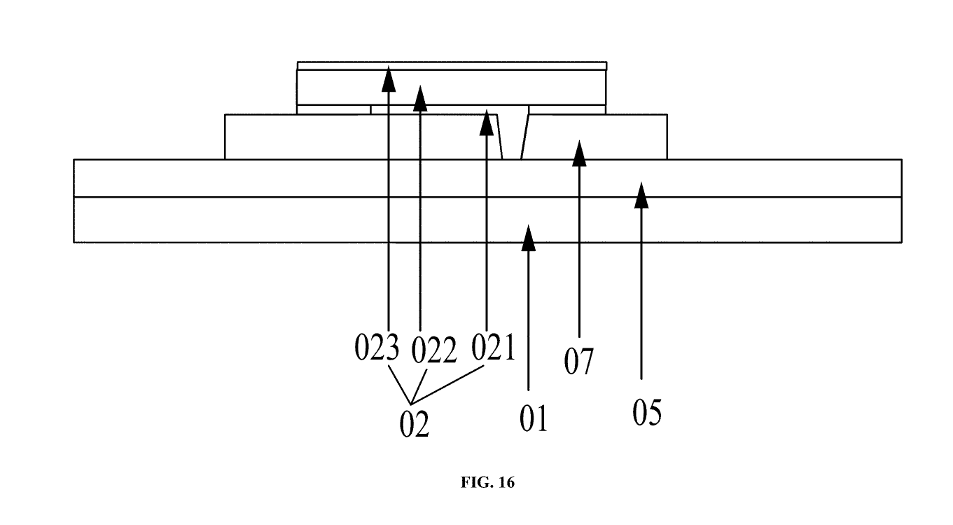

As shown in FIG. 16, after the plurality of pixel circuits are formed on the base substrate, a passivation layer 07 may also be formed on the pixel circuits. Afterwards, the OLEDs 02 can be formed on the pixel circuits 05 and the passivation layer 07. Here, the plurality of pixel circuits on the array substrate may be in one-to-one correspondence with the plurality of OLEDs, and each OLED may be connected to the corresponding pixel circuit by a via hole in the passivation layer 07.

In step 1404, a thin film encapsulation layer is formed on the OLEDs.

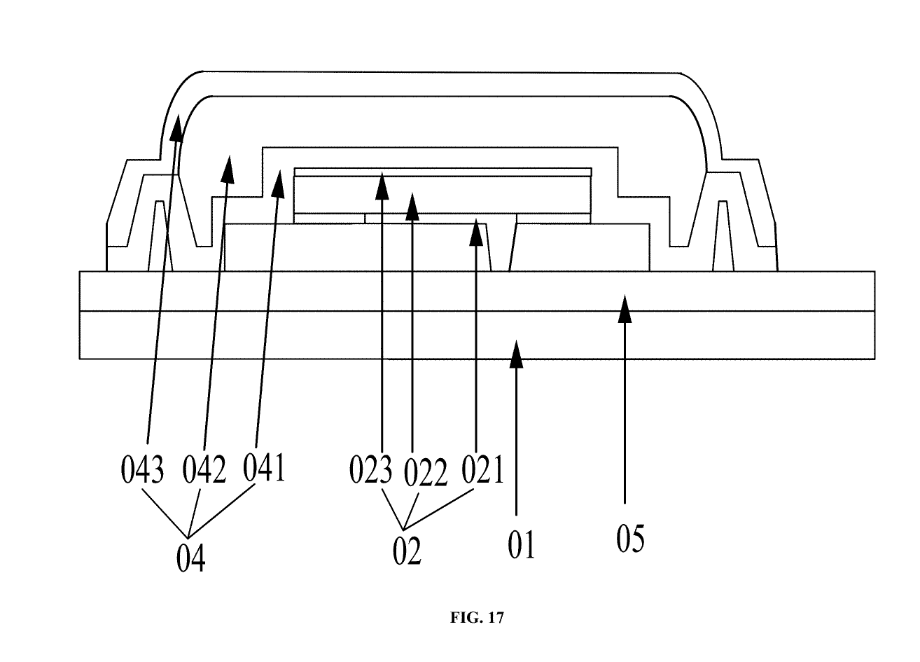

As shown in FIG. 17, after the plurality of OLEDs arranged in an array are formed, a thin film encapsulation layer 04 may be formed on the OLEDs, and the thin film encapsulation layer 04 may comprise a first silicon nitride layer 041, a silicon carbonitride layer 042 and a second silicon nitride layer 043 that are superposed together.

In step 1405, touch electrodes are formed on the thin film encapsulation layer, and the touch electrodes are disposed in the area of the base substrate where the OLEDs are not disposed.

In step 1406, n connecting wires in one-to-one correspondence to n touch areas are formed in a non-display area of the base substrate, one end of each of the n connecting wires is connected to a touch IC, and the other end of each connecting wire is connected to the touch electrode disposed in the corresponding touch area.

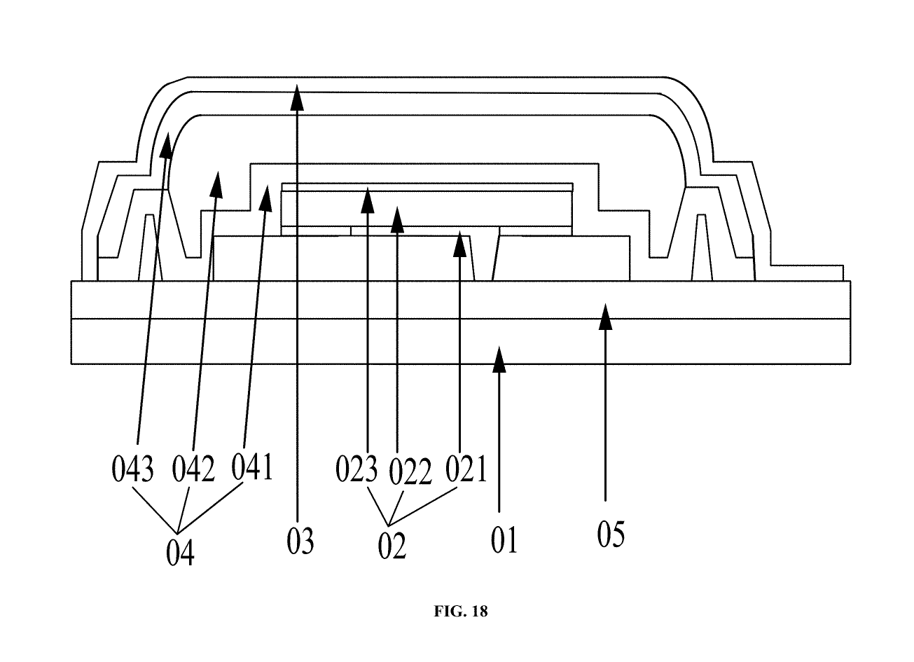

Referring to FIG. 18 and FIG. 2, after the thin film encapsulation layer is formed, the touch electrodes 03 and the connecting wires corresponding to the touch electrodes 03 may be formed on the thin film encapsulation layer. The touch electrodes 03 are located in a display area, the connecting wires are located in the non-display area, and the touch electrodes, the OLEDs and the connecting wires may be located on the same surface of the base substrate.

In step 1407, an insulating layer is formed on the thin film encapsulation layer.

As shown in FIG. 3, after the touch electrodes are formed, in order to prevent the touch electrodes from being in direct contact with the air, which causes the touch electrode to be oxidized and to lose the original characteristics thereof, the insulating layer 06 needs to be covered on the touch electrodes 03.

In addition, in order to prevent the touch electrode from being in direct contact with the air, which causes the touch electrode to be oxidized and to lose the original characteristics thereof, the insulating layer 06 needs to cover the touch electrode 03. Still referring to FIG. 3, the base substrate 01 provided with the touch electrodes 03 may be provided the insulating layer 06.

Optionally, the insulating layer can cover the touch electrodes without covering the connecting wires. The insulating layer may also cover the touch electrodes and the connecting wires at the same time, which is not limited by the embodiments of the present disclosure.

In step 1408, a cover layer is covered on the insulating layer.

After the insulating layer is formed, the cover plate may be covered on one side of the insulating layer away from the base substrate to obtain a display panel as shown in FIG. 4.

In summary, in the OLED display device manufactured according to the manufacturing method provided by the embodiments of the present disclosure, the position on the base substrate where the OLEDs are not disposed is provided with the touch electrode, and the touch electrode is connected to the touch IC. Therefore, the touch function can be realized directly through the touch IC and the touch electrode on the base substrate without superposing a touch panel on an OLED display panel, thereby reducing the number of the base substrates in the entire OLED display device and reducing the thickness of the entire OLED display device.

It should be noted that the embodiments of the OLED display device, the control method and manufacturing method thereof may be referred to each other, which is not limited in the embodiments of the present disclosure.

The foregoing descriptions are merely optional embodiments of the present disclosure, and are not intended to limit the present disclosure. Within the spirit and principles of the disclosure, any modifications, equivalent substitutions, improvements, etc., shall fall within the protection scope of the appended claims of the present disclosure.

What is claimed is:

1. An organic light-emitting diode (OLED) display device, comprising:
a base substrate, wherein a plurality of OLEDs in an array are disposed on the base substrate, an area of the base substrate where the OLEDs are not disposed is provided with touch electrodes; the touch electrodes are connected to a touch integrated circuit (IC) in the OLED display device, and the touch electrodes and the OLEDs are on the same surface of the base substrate.

2. The OLED display device according to claim 1, wherein the base substrate comprises n touch areas, n being an integer greater than or equal to 2, and
each of the touch areas of the base substrate is provided therein with a plurality of OLEDs, and the touch electrodes at gaps of adjacent OLEDs.

3. The OLED display device according to claim 2, wherein the base substrate comprises: a display area and a non-display area, and the display area comprises the n touch areas; and
the non-display area of the base substrate is provided therein with n connecting wires in one to one correspondence with the n touch areas, one end of each of the n connecting wires is connected to the touch IC, and the other end of each of the connecting wires is connected to the touch electrodes provided in the corresponding touch area.

4. The OLED display device according to claim 2, wherein four OLEDs in an array are disposed within each of the touch areas, the four OLEDs comprise two rows of OLEDs and two columns of OLEDs, and the touch electrodes are in a cross shape.

5. The OLED display device according to claim 1, wherein the touch electrode is a self-capacitance touch electrode.

6. The OLED display device according to claim 1, wherein the base substrate provided with the OLEDs is provided with a thin film encapsulation layer;
the base substrate provided with the thin film encapsulation layer is provided with the touch electrodes; and
the base substrate provided with the touch electrodes is provided with an insulating layer.

7. The OLED display device according to claim 6, wherein the thin film encapsulation layer comprises a first silicon nitride layer, a silicon carbonitride layer and a second silicon nitride layer which are sequentially superposed in a direction away from the base substrate, and the insulating layer is made of silicon nitride.

8. The OLED display device according to claim 3, wherein the material of the touch electrodes is the same as the material of the connecting wires.

9. The OLED display device according to claim 6, wherein the insulating layer covers the touch electrodes and the connecting wires.

10. The OLED display device according to claim 1, wherein the display device further comprises: a cover plate, and the OLEDs are between the base substrate and the cover plate.

11. A control method of an OLED display device, configured to control the OLED display device comprising: a base substrate, wherein a plurality of OLEDs in an array are disposed on the base substrate, an area of the base substrate where the OLEDs are not disposed is provided with touch electrodes, the touch electrodes are connected to a touch integrated circuit (IC) in the OLED display device, and the touch electrodes and the OLEDs are on the same surface of the base substrate, and the control method comprises:
during a touch period of the OLED display device, inputting, by a touch integrated circuit (IC), a touch alternating current (AC) signal to each of the touch electrodes in the OLED display device, and collecting a capacitance formed by each of the touch electrodes and the ground; and
determining, by the touch IC, whether each of the touch electrodes is touched according to the collected capacitance.

12. The method according to claim 11, wherein each OLED in the OLED display device is connected to a display control circuit, and the method further comprises:
during the touch period, inputting, by the display control unit, a display AC signal synchronized with the touch AC signal to a cathode of each OLED; and
during a display period of the OLED display device, inputting, by the display control circuit, a display direct current (DC) signal to the cathode of each OLED.

13. The method according to claim 12, wherein a value of amplitude of the touch AC signal is equal to a value of amplitude of the display AC signal.

14. The method according to claim 12, wherein the display control circuit comprises a gate electrode driving circuit and a display IC, the display control circuit has at least one signal terminal, each of the OLEDs is connected to the at least one signal terminal of the display control unit via a pixel circuit,
during the touch period, the signal on each signal terminal is an AC signal; and
during the display period, the signal on each signal terminal is a DC signal.

15. The method according to claim 14, wherein the at least one signal terminal comprises a power source signal terminal, and the method further comprises:
during the touch period, controlling, by the display control circuit, a circuit between an anode of each OLED and the power source signal terminal to be in an off state; and
during a light-emitting stage in the display period, controlling, by the display control circuit, the circuit between the anode of each OLED and the power source signal terminal to be in an on state.

16. The method according to claim 15, wherein the pixel circuit comprises eight transistors and a capacitor, the at least one signal terminal comprises: a reset terminal, a reference electrode terminal, a gate line terminal, a power source signal terminal, a data signal terminal, a control signal terminal, a reference signal input terminal and a cathode terminal, and the method further comprises:
during the touch period, controlling, by the display control circuit, the transistors having gate electrodes connected to the control signal terminal in the eight transistors to be in an off state; and
during the light-emitting stage in the display period, controlling, by the display control circuit, the transistors having the gate electrodes connected to the control signal terminal in the eight transistors to be in an on state.

17. The method according to claim 16, wherein
the eight transistors are one type of N-type transistors and P-type transistors.

18. A manufacturing method of an OLED display device, comprising:
providing a base substrate;
forming a plurality of OLEDs in an array on the base substrate; and
forming touch electrodes on the base substrate, wherein the touch electrodes are in an area of the base substrate where the OLEDs are not disposed, the touch electrodes are connected to a touch IC in the OLED display device, and the touch electrodes and the OLEDs are on the same surface of the base substrate.

19. The method according to claim 18, wherein the base substrate comprises: a display area and a non-display area, and the display area comprises n touch areas; the method further comprises:
forming n connecting wires in one to one correspondence with the n touch areas in the non-display area of the base substrate, wherein one end of each of the n connecting wires is connected to the touch IC, and the other end of each of the connecting wires is connected to the touch electrodes provided in the corresponding touch area.

20. The method according to claim 18, wherein after forming a plurality OLEDs in an array on the base substrate, the method further comprises: forming a thin film encapsulation layer on the base substrate;
forming touch electrodes on the base substrate comprises: forming the touch electrodes on the base substrate provided with the thin film encapsulation layer; and
after forming the touch electrodes on the base substrate, the method further comprises: forming an insulating layer on the base substrate provided with the touch electrodes.
